(19) United States
(12) Patent Application Publication
(10) Pub. No.: US 2015/0179826 A1
(43) Pub. Date: Jun. 25, 2015

(54) DIODE DEVICE AND METHOD OF MANUFACTURING THE SAME

(71) Applicant: SAMSUNG ELECTRO-MECHANICS CO., LTD., Suwon-Si (KR)

(72) Inventors: Chang Su JANG, Suwon-Si (KR); Yoon Seong KIM, Suwon-Si (KR); Kyu Hyun MO, Suwon-Si (KR); Dong Soo SEO, Suwon-Si (KR); Jae Kyu SUNG, Suwon-Si (KR)

(73) Assignee: SAMSUNG ELECTRO-MECHANICS CO., LTD., Suwon-Si (KR)

(21) Appl. No.: 14/274,084

(22) Filed: May 9, 2014

(30) Foreign Application Priority Data
Dec. 23, 2013 (KR) 10-2013-0161512

(51) Int. Cl. H01L 29/872; H01L 29/66

(52) U.S. Cl. CPC H01L 29/8725; H01L 29/66143

(57) ABSTRACT

A diode device may include: a first semiconductor area having a first conductivity type; a second semiconductor area having a second conductivity type, provided on the first semiconductor area and having a uniform impurity density; a trench provided to pass through the second semiconductor area to contact the first semiconductor area; and a first metal layer provided on surfaces of the trench and the second semiconductor area.

### CROSS-REFERENCE TO RELATED APPLICATION

This application claims the benefit of Korean Patent Application No. 10-2013-0161512 filed on Dec. 23, 2013, with the Korean Intellectual Property Office, the disclosure of which is incorporated herein by reference.

### BACKGROUND

The present disclosure relates to a diode device and a method of manufacturing the same.

A diode refers to a semiconductor device having light-emitting, rectifying characteristics or the like.

A diode may be formed to have a p-n junction, formed by bringing a p-type semiconductor and an n-type semiconductor into contact with one another.

When a p-n junction is formed by a contact between a p-type semiconductor and an n-type semiconductor, electrons existing in the n-type semiconductor may be diffused into the p-type semiconductor.

The diffused electrons combine with holes in the p-type semiconductor area, and a depletion area in which no carriers exist is formed in a portion of the p-n junction.

When a positive (+) voltage is applied to the p-type semiconductor area and a negative (−) voltage is applied to the n-type semiconductor area, the depletion area may be removed and a current may flow through the diode accordingly.

In contrast, if a reverse bias is applied, for example, by applying a negative (−) voltage to the p-type semiconductor area and a positive (+) voltage to the n-type semiconductor area, the depletion area having no carriers may further extend, and thus, no current may flow through the diode.

Recently, in high speed switching diodes, soft recovery characteristics are required in addition to fast switching characteristics.

A p-n junction diode, a typically used diode from among a range of diodes, uses minority carriers, and thus a forward voltage may be reduced in the p-n junction diode due to a conduction modulation effect.

However, high speed switching characteristics are degraded by the reverse recovery characteristics of the minority carriers.

The reverse recovery characteristics refer to a phenomenon in which a high reverse current instantaneously flows when a voltage is applied abruptly in a reverse direction while a forward current is applied to the p-n junction diode, due to a reverse flow of injected minority carriers in the p-n junction, the reverse current referring to a current that flows until the minority carriers are extinguished or removed.

A high speed switching diode has soft recovery characteristics by reducing a period until a reverse current reaches a level of 0 (reverse recovery time: trr) and by smoothing a waveform of the reverse current.

A high speed switching diode may be classified as a fast recovery diode (FRD), a high efficiency diode (HED), and a Schottky barrier diode (SBD).

From among these, an FRD has the same structure as a typical p-n diode but allows minority carriers to be quickly extinguished after a turn-off by diffusing impurities such as platinum or gold into silicon, by using an electronic line or irradiation of neutrons to thereby increase a recombination center of electrons and holes.

In the FRD, injection efficiency in an anode portion is inevitably increased, and this may degrade switching characteristics.

To improve switching characteristics, a Merged PiN/Schottky (MPS) structure has been used in the related art.

An MPS structure refers to a structure in which a p-n junction, in which a current flows, and a Schottky junction, are alternately formed.

The invention disclosed in Patent Document 1 according to the related art below relates to a diode having an MPS structure as described above.

### RELATED ART DOCUMENT

(Patent Document 1) U.S. Pat. No. 4,982,260

### SUMMARY

An aspect of the present disclosure may provide a diode device having a Merged PIN/Schottky (MPS) structure and improved switching characteristics and a method of manufacturing the same.

According to an aspect of the present disclosure, a diode device may include: a first semiconductor area having a first conductivity type; a second semiconductor area having a second conductivity type, provided on the first semiconductor area and having a uniform impurity density; a trench provided to pass through the second semiconductor area to contact the first semiconductor area; and a first metal layer provided on surfaces of the trench and the second semiconductor area.

The first metal layer may form a Schottky junction with the first semiconductor area, and may form an Ohmic junction with the second semiconductor area.

The second semiconductor area may include polysilicon.

The diode device may further include a buffer area having a first conductivity type, provided below the first semiconductor area and having a higher impurity density than the first semiconductor area.

The diode device may further include a second metal layer provided below the first semiconductor area and forming an Ohmic junction with the first semiconductor area.

According to another aspect of the present disclosure, a method of manufacturing a diode device, the method may include: providing a first semiconductor area having a first conductivity type; growing a second semiconductor area having a second conductivity type, on the first semiconductor area by an epitaxial method; forming a trench contacting the first semiconductor area by etching the second semiconductor area; and forming a first metal layer on the trench and the second semiconductor area by depositing a metal.

The first metal layer may form a Schottky junction with the first semiconductor area, and may form an Ohmic junction with the second semiconductor area.

The growing of the second semiconductor area may be performed by using polysilicon.

The method may further include growing a buffer area having a first conductivity type below the first semiconductor area by an epitaxial method, the buffer area having a higher impurity density than the first semiconductor area.

The method may further include forming a second metal layer by depositing a metal below the first semiconductor area, the second metal layer forming an Ohmic junction with the first semiconductor area.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a schematic cross-sectional view illustrating a diode device according to an exemplary embodiment of the present disclosure;

FIG. 2 shows impurity density according to a depth and a width of a diode device manufactured according to the related art;

FIG. 3 shows impurity density according to a depth and a width of a diode device according to an exemplary embodiment of the present disclosure;

FIG. 4 is a graph illustrating an injection amount of impurities according to depth;

FIG. 5 is a graph illustrating measurement of a variation in current during a switching operation of a diode device according to an exemplary embodiment of the present disclosure; and

FIG. 6 is an enlarged view of portion B of FIG. 5.

### DETAILED DESCRIPTION

Hereinafter, embodiments of the present disclosure will be described in detail with reference to the accompanying drawings.

The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements.

A power switch may be formed of one of a power metal oxide semiconductor field effect transistor (MOSFET), an insulated gate bipolar transistor (IGNT), a thyristor, and the like. Descriptions of most novel techniques described herein will focus on diodes; however, various embodiments of the present disclosure are not limited to a diode. The present inventive concept may also be applied to different types of power switch technology including power MOSFETs or other types of thyristor. Moreover, according to exemplary embodiments of the present disclosure, it is described that particular p-type and n-type areas are included. However, it is obvious that the embodiments of the present disclosure may also be applied to a device having areas of opposite conductivity types disclosed herein.

In addition, n-type and p-type, as used hereinafter, may be respectively defined as a first conductivity type and a second conductivity type. Meanwhile, the first conductivity type and the second conductivity type refer to conductivity types that are different from each other.

In addition, generally, positive ‘+’ refers to a highly-doped state, and negative ‘−’ refers to a sparsely-doped state.

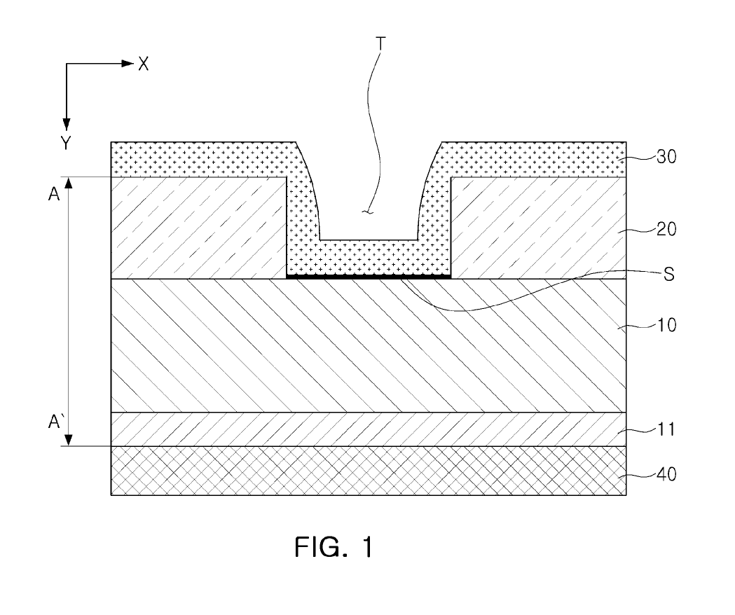

FIG. 1 is a schematic cross-sectional view illustrating a diode device according to an exemplary embodiment of the present disclosure.

The diode device according to an exemplary embodiment of the present disclosure may be formed of a first semiconductor area 10 having a first conductivity type and a second semiconductor area 20 having a second conductivity type.

In detail, the diode device according to this exemplary embodiment of the present disclosure may include the first semiconductor area 10 having a first conductivity type; the second semiconductor area 20 having a second conductivity type, formed on the first semiconductor area 10 and having a uniform impurity density; a trench T formed to pass through the second semiconductor area 20 to contact the first semiconductor area 10; and a first metal layer 30 formed on surfaces of the trench T and the second semiconductor area 20.

The first conductivity type may be an n-type, and the second conductivity type may be a p-type.

In general, the first semiconductor area 10 may be an n-type semiconductor area having a low impurity density.

The second semiconductor area 20 may be a p-type semiconductor area.

When the first semiconductor area 10 and the second semiconductor area 20 contact each other, electrons and holes existing in the first semiconductor area 10 and the second semiconductor area 20 combine with each other.

Accordingly, a depletion area is formed in a portion of the diode device in which the first semiconductor area 10 and the second semiconductor area 20 contact each other.

If reverse bias is applied to the diode device, the depletion area further extends and no carriers exist therein, and thus, no current flows through the diode device.

That is, in a reverse-bias area, a current flowing through the diode device is extremely small.

However, if a voltage that exceeds a reverse limit voltage or a breakdown voltage is supplied to the diode device, an avalanche breakdown occurs, so that a high current flows in a reverse direction, destroying the diode device.

Thus, in order to increase breakdown voltage, the first semiconductor area 10 needs to have a thickness sufficient to allow the depletion area to be sufficiently extended.

A buffer area 11 having a first conductivity type may be further formed below the first semiconductor area 10 of the diode device according to an exemplary embodiment of the present disclosure.

The buffer area 11 may have a higher impurity density than an impurity density of the first semiconductor area 10.

The buffer area 11 may prevent extension of the depletion area by having a higher impurity density than the impurity density of the first semiconductor area 10.

Accordingly, when the buffer area 11 is formed, a thickness of the first semiconductor area 10 may be reduced.

To improve switching characteristics, the diode device according to the exemplary embodiment of the present disclosure may have a Merged PiN/Schottky (MPS) structure according to the related art.

An MPS structure refers to a structure in which a p-n junction, in which a current flows, and a Schottky junction S, are alternately formed.

In general, in an MPS structure, an n-type semiconductor area in a portion of the MPS structure in which a Schottky junction S is formed functions as a resistor.

That is, a current flowing through the Schottky junction S is a current that flows due to electrons, and the area functioning as the resistor causes a voltage drop.

Accordingly, the voltage drop may be reduced by removing a portion of the n-type semiconductor area in the portion in which the Schottky junction S is formed.

In the diode device according to the exemplary embodiment of the present disclosure, the trench T may be formed to contact the first semiconductor area 10 by passing through the second semiconductor area 20.

The trench T may be formed to expose a portion of the first semiconductor area 10.

That is, as a thickness of the first semiconductor area 10 is reduced in a portion thereof in which the trench T is formed, a thickness of the portion that functions as a resistor is reduced.

Accordingly, a voltage drop of the current flowing through the Schottky junction S may be minimized.

A depth of the trench T may be sufficient as long as the trench T exposes a portion of the first semiconductor area 10, and if the trench T has a depth greater than the above depth, a breakdown voltage BV may be reduced.

The first metal layer 30 may be formed on surfaces of the trench T and the second semiconductor area 20.

The first metal layer 30 may have a Schottky junction with the first semiconductor area 10.

Also, the first metal layer 30 may have an Ohmic junction with the second semiconductor area 20.

A material of the first metal layer 30 is not particularly limited as long as a metal therein has a Schottky junction with the first semiconductor area 10.

In detail, the first metal layer 30 may include any one selected from the group consisting of Ti, Cr, Nb, Sn, W, Ni, Pt, and Ta, but is not limited thereto.

The first metal layer 30 may have a single layer structure or a multilayer structure.

Furthermore, the first metal layer 30 may be formed to completely fill the trench T, but is not limited thereto.

For example, the first metal layer 30 may be disposed on a lower surface and lateral surfaces of the trench T, and an inner portion of the trench T may be empty space.

A second metal layer 40 may further be formed below the first semiconductor area 10.

The second metal layer 40 may be formed of a metal that has an Ohmic junction with the first semiconductor area 10.

For example, the second metal layer 40 may be formed of Al or Ag, but is not limited thereto.

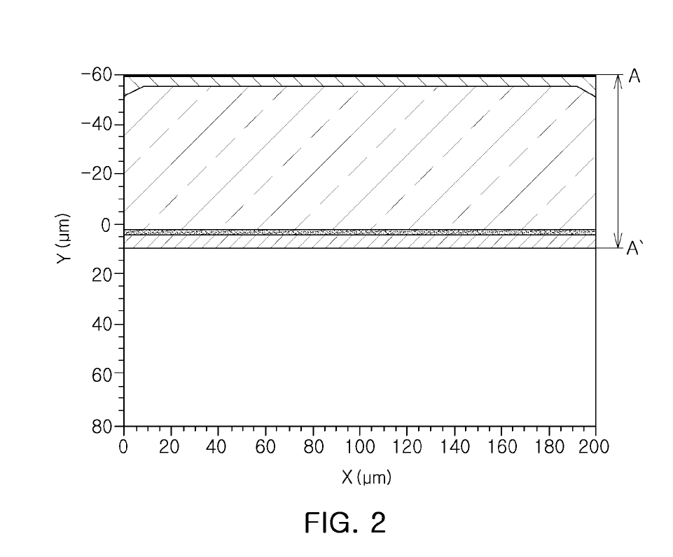

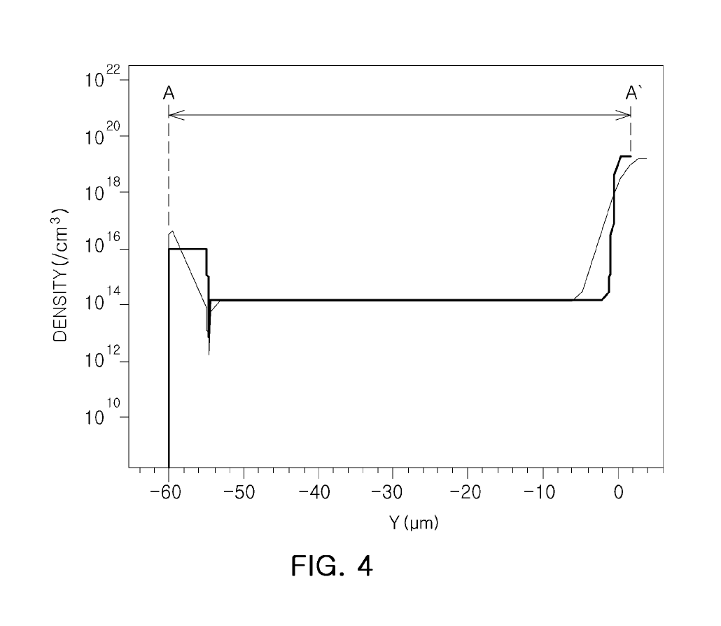

FIG. 2 illustrates layers of a diode device (Comparative Example) manufactured according to the related art which are divided according to an impurity density depending on a depth and a width of the diode device. FIG. 4 is a graph illustrating an injection amount of impurities according to depth (solid line: Inventive Example, thin line: Comparative Example).

The diode device illustrated in FIG. 2, manufactured according to the method of the related art, is capable of withstanding the same degree of resistance pressure as the diode device according to an exemplary embodiment of the present disclosure.

Referring to FIG. 2 illustrating an impurity density according to a depth and a width of the diode device manufactured according to the related art, the diode device may be largely divided into five layers from below.

In FIG. 2, a lowermost layer corresponds to a buffer area, and a third layer from below denotes an area corresponding to a first semiconductor area, and a fourth layer from below denotes an area corresponding to a second semiconductor area.

As illustrated in FIG. 2, a diffusion area of about 2 μm is formed between the buffer area and the first semiconductor area.

A sum of a thickness of the diffusion area and a thickness of the buffer area is about 8 μm.

Referring to FIG. 4, an impurity density of the buffer area according to the Comparative Example is an average of about 1.7e+18/cm³.

The buffer area according to the Comparative Example has the highest impurity density in a lower portion thereof, that is, in which the buffer area begins from below, and the impurity density thereof gradually decreases in an upward direction.

Referring to FIG. 4, the first semiconductor area of the Comparative Example has a uniform density of about 1.0e+14/cm³.

The second semiconductor area of the Comparative Example may have an average impurity density of about 1.0e+16/cm³.

However, an upper portion of the second semiconductor area of the Comparative Example has a high impurity density of 2.0e+16/cm³.

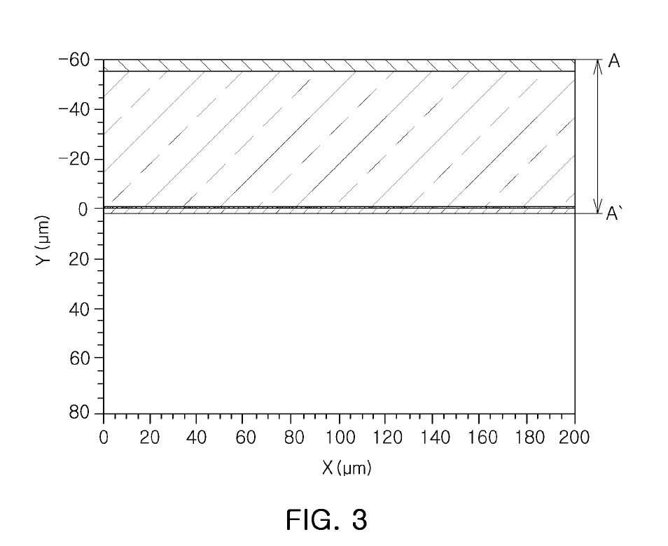

FIG. 3 illustrates layers of a diode device (Inventive Example) according to an exemplary embodiment of the present disclosure which are divided according to an impurity density depending on a depth and a width of the diode device.

Referring to FIG. 3 illustrating an impurity density according to a depth and a width of the diode device according to an exemplary embodiment of the present disclosure, the diode device may be largely divided into four layers from below.

In FIG. 3, a lowermost layer corresponds to the buffer area 11, and a third layer from below denotes an area corresponding to the first semiconductor area 10, and a fourth layer from below denotes an area corresponding to the second semiconductor area 20.

Referring to FIG. 4, the buffer area 11 of the Inventive Example has an impurity density of about 1.7e+18/cm³.

While the impurity density of the related art diode device illustrated in FIG. 2 is varied according to depth, the diode device according to the exemplary embodiment of the present disclosure may have a uniform impurity density regardless of depth.

As shown in FIG. 3, although a diffusion area is formed between the buffer area 11 and the first semiconductor area 10, the diffusion area has a thickness of about 1 μm or less.

Accordingly, in the diode device according to the exemplary embodiment of the present disclosure, a sum of the thickness of the diffusion area and the thickness of the buffer area may merely be about 5 μm or less.

That is, compared to the diode device of FIG. 2, the diode device according to the exemplary embodiment of the present disclosure may withstand the same resistance pressure but may have a reduced thickness.

Also, when referring to FIG. 4, the second semiconductor area 20 of the Inventive Example may have an impurity density of about 1.0e+16/cm³.

That is, the impurity density of the second semiconductor area 20 of the Inventive Example and an average impurity density of the second semiconductor area of the Comparative Example are the same.

However, the impurity density of the second semiconductor area 20 of the Inventive Example is not varied according to depth, but is uniform.

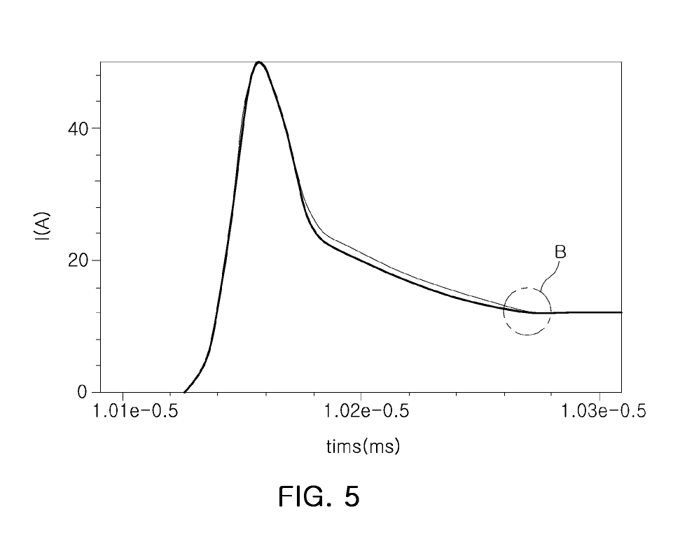

The effects resulted from the differences between the Inventive Example and the Comparative Example will be described with reference to FIG. 5.

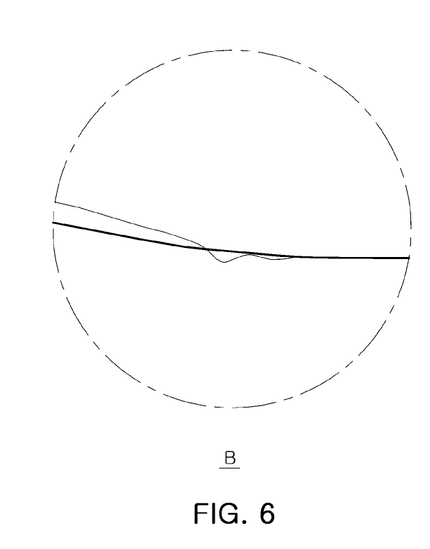

FIG. 5 is a graph illustrating measurement of a variation in current during a switching operation of a diode device according to an exemplary embodiment of the present disclosure (solid line: Inventive Example, thin line: Comparative Example). FIG. 6 is an enlarged view of portion B of FIG. 5.

Referring to FIG. 5, a current in the diode device according to the Inventive Example converges faster than in the diode device according to the Comparative Example.

That is, after a peak is reached in the graph of FIG. 5, the solid line is further below the thin line and converges faster toward a uniform value as compared with the thin line.

Thus, this indicates that the diode device according to the exemplary embodiment of the present disclosure has excellent high speed switching performance.

That is, in the diode device according to the exemplary embodiment of the present disclosure, an impurity density of the second semiconductor area 20 is uniform regardless of the depth, and the diode device has improved high speed switching performance since an impurity density thereof at a predetermined depth is not considerably varied.

Furthermore, as shown in FIG. 6, according to the Comparative Example, a current level decreases while a current is fluctuating; however, in the diode device according to the exemplary embodiment of the present disclosure, fluctuations in a current smoothly converge to a uniform value.

Thus, the diode device according to the exemplary embodiment of the present disclosure has excellent smooth recovery characteristics.

A method of manufacturing a diode device according to another exemplary embodiment of the present disclosure may include: providing a first semiconductor area having a first conductivity type; growing a second semiconductor area having a second conductivity type, on the first semiconductor area by an epitaxial method; forming a trench in contact with the first semiconductor area by etching the second semiconductor area; and forming a first metal layer by depositing a metal on the trench and the second semiconductor area.

The providing of a first semiconductor area may be performed by using a semiconductor substrate doped with n-type impurities at a low density.

In the providing of the first semiconductor area, a semiconductor substrate having a sufficient thickness may be provided. A front surface of the semiconductor substrate may first be processed and then a portion of a rear surface thereof may be removed before the rear surface thereof is processed to thereby appropriately adjust the thickness of the semiconductor substrate.

After the providing of the first semiconductor area, a second semiconductor area having a second conductivity type may be grown on the first semiconductor area using an epitaxial method.

The forming of the second semiconductor area may be performed under an atmosphere of a uniform impurity density while the epitaxial method is being performed, so that the second semiconductor area has a uniform impurity density regardless of depth.

Also, the second semiconductor area may be formed by growing polysilicon by an epitaxial method, but is not limited thereto.

As the second semiconductor area is formed by injecting second conductivity type impurities in the related art, a second conductivity type impurity density on a surface of the second semiconductor area is very high. However, in the method of manufacturing a diode device according to the exemplary embodiment of the present disclosure, an impurity density in a certain portion of the second semiconductor area is not varied.

After the forming of the second semiconductor area, a portion of the second semiconductor area may be etched to form a trench.

The trench may be formed to expose a portion of the first semiconductor area.

Then, a first metal layer may be formed on a surface of the trench.

For example, the first metal layer may be formed on surfaces of the trench and the second semiconductor area.

The first metal layer may be formed of a metal that forms a Schottky junction with the first semiconductor area.

In detail, the first metal layer 30 may include any one metal selected from the group consisting of Ti, Cr, Nb, Sn, W, Ni, Pt, and Ta, but is not limited thereto.

The manufacturing method may further include growing a buffer area having a first conductivity type, which has a higher impurity density than an impurity density of the first semiconductor area below the first semiconductor area by an epitaxial method.

As the buffer area is formed by an epitaxial method, the buffer area may have a reduced thickness as compared to a buffer layer of the related art.

That is, the diode device manufactured by the method of manufacturing a diode device according to the exemplary embodiment of the present disclosure has a reduced thickness as compared to a diode device of the related art but may withstand the same resistance pressure.

The manufacturing method may further include forming a second metal layer that forms an Ohmic junction with the first semiconductor area by depositing a metal below the first semiconductor area.

As set forth above, according to exemplary embodiments of the present disclosure, a diode device may have a uniform impurity density regardless of a depth of a second semiconductor area having a p-type conductivity type, and thus, the second semiconductor area may have a reduced thickness.

Accordingly, the diode device according to the exemplary embodiment of the present disclosure may have smooth recovery characteristics during a switching operation.

In a method of manufacturing a diode device according to another exemplary embodiment of the present disclosure, a second semiconductor area may be formed by an epitaxial method to thereby precisely adjust a thickness of the second semiconductor area, and may have a uniform impurity density regardless of depth.

Consequently, in the diode device manufactured using the method of manufacturing a diode device according to the exemplary embodiment of the present disclosure, the second semiconductor area may have a reduced thickness, and the diode device may have smooth recovery characteristics during a switching operation.

While exemplary embodiments have been shown and described above, it will be apparent to those skilled in the art that modifications and variations could be made without departing from the spirit and scope of the present disclosure as defined by the appended claims.

What is claimed is:

1. A diode device, comprising:
a first semiconductor area of first conductivity type;
a second semiconductor area of second conductivity type provided on the first semiconductor area and having a uniform impurity density;
a trench passing through the second semiconductor area to contact the first semiconductor area; and
a first metal layer provided on surfaces of the trench and the second semiconductor area.

2. The diode device of claim 1, wherein the first metal layer forms a Schottky junction with the first semiconductor area and forms an Ohmic junction with the second semiconductor area.

3. The diode device of claim 1, wherein the second semiconductor area includes polysilicon.

4. The diode device of claim 1, further comprising a buffer area having a first conductivity type, provided below the first semiconductor area and having a higher impurity density than the first semiconductor area.

5. The diode device of claim 1, further comprising a second metal layer provided below the first semiconductor area and forming an Ohmic junction with the first semiconductor area.

6. A method of manufacturing a diode device, the method comprising:
providing a first semiconductor area of first conductivity type;
growing a second semiconductor area of second conductivity type on the first semiconductor area by an epitaxial method;
forming a trench contacting the first semiconductor area by etching the second semiconductor area; and
forming a first metal layer on surfaces of the trench and the second semiconductor area by depositing a metal.

7. The method of claim 6, wherein the first metal layer forms a Schottky junction with the first semiconductor area and forms an Ohmic junction with the second semiconductor area.

8. The method of claim 6, wherein the growing of the second semiconductor area is performed by using polysilicon.

9. The method of claim 6, further comprising growing a buffer area having a first conductivity type below the first semiconductor area by an epitaxial method, the buffer area having a higher impurity density than the first semiconductor area.

10. The method of claim 6, further comprising forming a second metal layer by depositing a metal below the first semiconductor area, the second metal layer forming an Ohmic junction with the first semiconductor area.
